(19) United States
(12) Patent Application Publication
(10) Pub. No.: US 2024/0426895 A1
(43) Pub. Date: Dec. 26, 2024

(54) CONTACT RESISTANCE TEST STRUCTURE FOR STACKED FETS

(71) Applicant: International Business Machines Corporation, Armonk, NY (US)

(72) Inventors: Huimei Zhou, Albany, NY (US); Chen Zhang, Santa Clara, CA (US); Miaomiao Wang, Albany, NY (US); Junli Wang, Slingerlands, NY (US)

(21) Appl. No.: 18/341,003

(22) Filed: Jun. 26, 2023

(51) Int. Cl. G01R 31/26; G01R 27/20

(52) U.S. Cl. CPC G01R 31/2621; G01R 27/205

(57) ABSTRACT

A semiconductor test structure includes a first transistor active area comprising at least a first source/drain region, and a second transistor active area stacked on the first transistor active area and comprising at least a second source/drain region. At least one dielectric layer is disposed between the first transistor active area and the second transistor active area. The semiconductor test structure further includes a plurality of contact structures spaced apart from each other and disposed on the second source/drain region, and at least one gate structure extending across the first transistor active area and the second transistor active area. Contact resistance is measured between respective ones of the plurality of contact structures and the second source/drain region, and the second source/drain region is continuous between the plurality of contact structures.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide structures used for testing contact resistance in stacked FETs.

In one embodiment, a semiconductor test structure includes a first transistor active area comprising at least a first source/drain region, and a second transistor active area stacked on the first transistor active area and comprising at least a second source/drain region. At least one dielectric layer is disposed between the first transistor active area and the second transistor active area. The semiconductor test structure further includes a plurality of contact structures spaced apart from each other and disposed on the second source/drain region, and at least one gate structure extending across the first transistor active area and the second transistor active area. Contact resistance is measured between respective ones of the plurality of contact structures and the second source/drain region, and the second source/drain region is continuous between the plurality of contact structures.

In another embodiment, a semiconductor test structure includes a first active area comprising at least a first nanosheet transistor structure and a first source/drain region corresponding to the first nanosheet transistor structure. The first nanosheet transistor structure comprises a first plurality of gate structures alternately stacked with a first plurality of channel layers. A second active area is stacked on the first active area and comprises at least a second nanosheet transistor structure and a second source/drain region corresponding to the second nanosheet transistor structure. The second nanosheet transistor structure comprises a second plurality of gate structures alternately stacked with a second plurality of channel layers. At least one dielectric layer is disposed between the first active area and the second active area. A plurality of contact structures are spaced apart from each other and disposed on the second source/drain region. Contact resistance is measured between respective ones of the plurality of contact structures and the second source/drain region, and the second source/drain region is continuous between the plurality of contact structures.

In another embodiment, a semiconductor test structure includes a substrate and a first active area comprising a first source/drain region disposed on the substrate, wherein the first source/drain region has a first doping type. A dielectric layer is disposed on the first source/drain region. The semiconductor test structure further includes a second active area comprising a second source/drain region disposed on the dielectric layer, wherein the second source/drain region has a second doping type different from the first doping type. A plurality of contact structures are spaced apart from each other and disposed on the second source/drain region, and at least one gate structure extends across at least the second active area. Contact resistance is measured between respective ones of the plurality of contact structures and the second source/drain region, and the second source/drain region is continuous between the plurality of contact structures.

These and other features and advantages of embodiments described herein will become more apparent from the accompanying drawings and the following detailed description.

### BRIEF DESCRIPTION OF THE DRAWINGS

FIG. 1 is a top view illustrating a semiconductor test structure, according to an embodiment of the invention.

FIG. 2A is a schematic cross-sectional view taken along line A of FIG. 1 and illustrating the semiconductor test structure, according to an embodiment of the invention.

FIG. 2B is a schematic cross-sectional view illustrating another contact structure for the semiconductor test structure, according to an embodiment of the invention.

FIG. 3 is a schematic cross-sectional view taken along part of line B of FIG. 1 and illustrating the semiconductor test structure, according to an embodiment of the invention.

FIG. 4 is a schematic cross-sectional view taken along part of line C of FIG. 1 and illustrating the semiconductor test structure, according to an embodiment of the invention.

FIG. 5 is a top view illustrating a semiconductor test structure, according to an embodiment of the invention.

FIG. 6 is a top view illustrating a semiconductor test structure, according to an embodiment of the invention.

### DETAILED DESCRIPTION

Illustrative embodiments of the invention may be described herein in the context of illustrative methods for forming semiconductor structures used for testing contact resistance in stacked FETs, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers may be used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

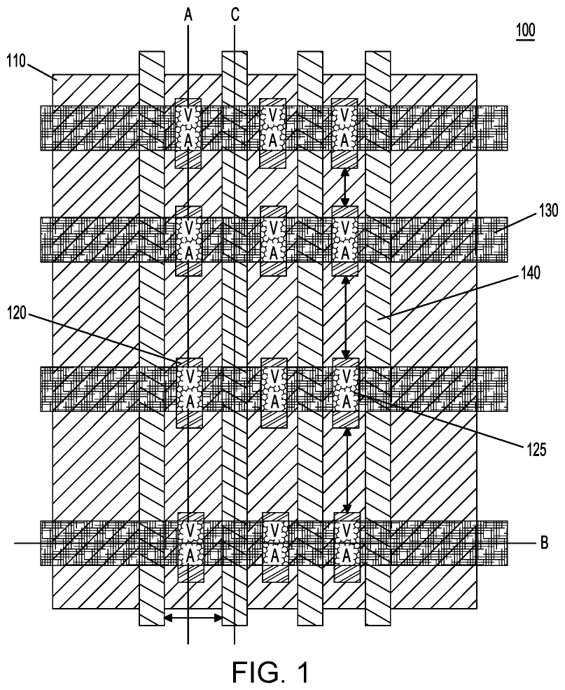

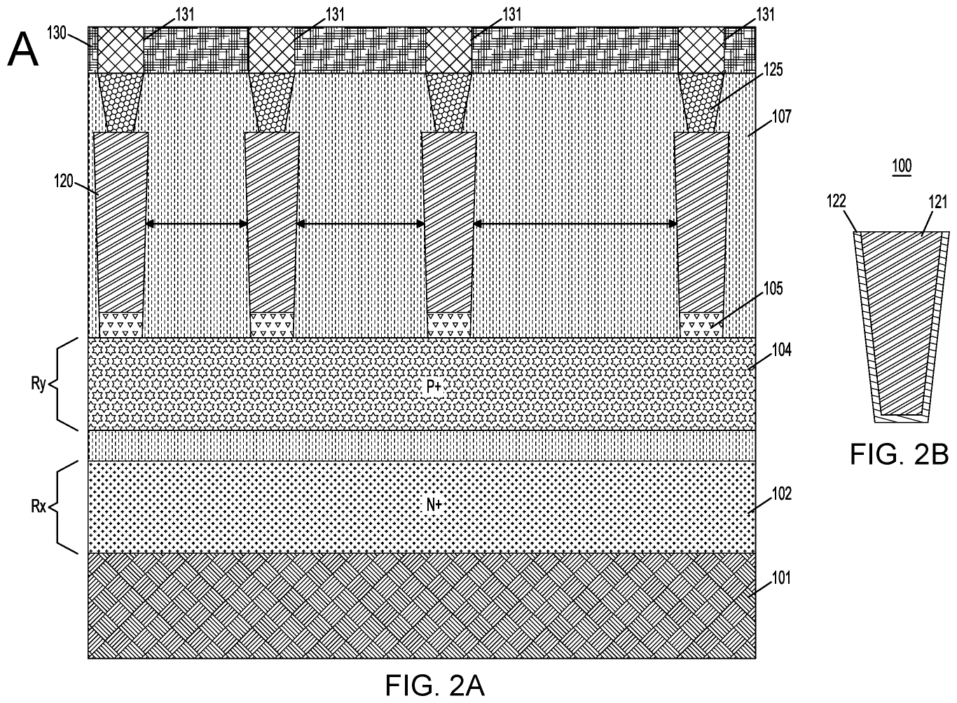

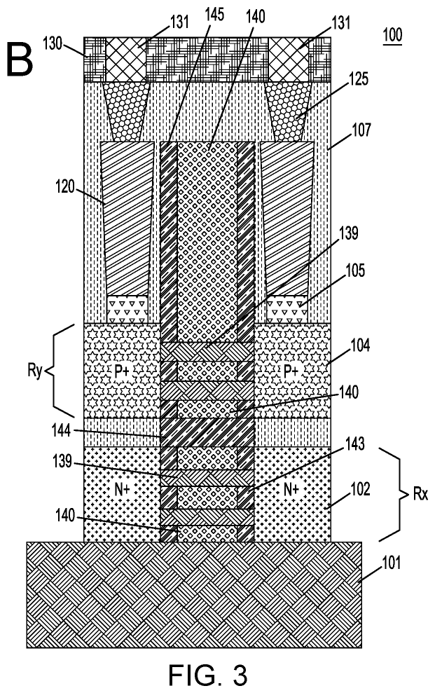

Referring to the top view of the semiconductor test structure 100 in FIG. 1 and the cross-sectional views of the semiconductor test structure 100 in FIGS. 2A and 3, a semiconductor substrate 101 comprises semiconductor material including, but not limited to, silicon (Si), silicon germanium (SiGe), III-V, II-V compound semiconductor materials or other like semiconductor materials. In addition, multiple layers of the semiconductor materials can be used as the semiconductor material of the substrate.

A first transistor active area (Rx) comprises a first nanosheet stacked structure including a first plurality of gate structures 140 alternately stacked with a first plurality of channel layers 139. A second transistor active area (Ry) comprises a second nanosheet stacked structure, wherein the second stacked structure comprises a second plurality of gate structures 140 alternately stacked with a second plurality of channel layers 139. In the top view of FIG. 1. Rx and Ry overlap with each other and are designated by reference numeral 110. The first transistor active area Rx comprises a first plurality of source/drain regions 102 disposed on sides of the first stacked structure, and the second transistor active area Ry comprises a second plurality of source/drain regions 104 disposed on sides of the second stacked structure. The first source/drain region 102 has a different doping type (e.g., N+) than the second source/drain region 104 (e.g., P+). It is to be understood that the cross-sectional view in FIG. 3 is taken along part of line B in FIG. 1, and that the semiconductor test structure 100 includes multiple stacked structures of first and second pluralities of gate structures 140 and first and second pluralities of channel layers 139, and corresponding first and second source/drain regions 102 and 104.

In illustrative embodiments, a size of the first transistor active area Rx is equal to a size of the second transistor active area Ry. For example, the area of the first transistor active area Rx is equal to the area of the second transistor active area Ry, and the first and second transistor active areas Rx and Ry can have the same dimensions (e.g., length, width, depth). The embodiments of the present invention are not necessarily limited to the shown number of gate structures and channel layers 140, 139, and there may be more or less layers in the same alternating configuration depending on design constraints.

In forming the first and second stacked structures, alternating layers of, for example, Si and sacrificial SiGe are formed in a configuration corresponding to the alternating configurations of the first and second pluralities of gate structures 140 and the and first and second pluralities of channel layers 139. The sacrificial SiGe layers and Si layers are epitaxially grown in an alternating and stacked configuration on the semiconductor substrate 101 and from their corresponding underlying semiconductor layers. The sacrificial SiGe layers are referred to herein as sacrificial semiconductor layers since, as described further herein, the at least part of the sacrificial SiGe layers are eventually removed and replaced by the gate structures 140. The silicon layers become the channel layers 139 of the stacked structures.

Although SiGe is described as a sacrificial material for sacrificial SiGe layers, and Si is described as the material of the channel layers, other materials can be used as long as the sacrificial material has the property of being able to be removed selectively compared to the material of the channel layers.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a majority portion of the upper-most gate structure 140 replaces a previously formed dummy gate portion including, for example, amorphous silicon (a-Si). A lower portion of the upper-most gate structure 140 replaces a removed uppermost sacrificial SiGe layer or a removed portion of the uppermost sacrificial SiGe layer. Gate spacers 145 are formed on lateral sides of the upper-most gate structure 140. The spacer material can comprise for example, one or more dielectrics, including, but not necessarily limited to, silicon nitride (SiN), silicon carbide (SiC), silicon oxynitride (SiON), SiOC, silicon-carbon-nitride (SiCN), boron nitride (BN), silicon boron nitride (SiBN), silicoboron carbonitride (SiBCN), silicon oxycarbonitride (SiOCN), silicon oxide (SiOₓ) (where x is for example, 2, 1.99 or 2.01), and combinations thereof. The gate spacers 145 can be formed by any suitable techniques such as deposition followed by directional etching. Deposition may include but is not limited to, atomic layer deposition (ALD) or chemical vapor deposition (CVD). Directional etching may include but is not limited to, reactive ion etching (RIE).

Due to the germanium in sacrificial SiGe layers, lateral etching of the sacrificial SiGe layers can be performed selective to the channel layers 139 (e.g., Si channel layers), such that the side portions of the sacrificial SiGe layers can be removed to create vacant areas to be filled in by inner spacers 143. Such etching can be performed using, for example, NH₄OH: H₂O₂ solution. Inner spacer material is formed on lateral sides of the sacrificial SiGe layers and fills in the vacant portions left by the lateral recessing of the sacrificial SiGe layers. In accordance with an embodiment, the inner spacer material can comprise a dielectric including, but not necessarily limited to, an oxide, such as SiOₓ, TiOₓ, AlOₓ, etc. A dielectric layer 144 having the same or a similar material to that of the gate spacers 145 and/or inner spacers 143 is disposed between the first and second nanosheet stacked structures.

The first and second source/drain regions 102 and 104 are epitaxially grown from and contact exposed sides of the channel layers 139 of the nanosheet stacks. The first source/drain regions 102 may also be epitaxially grown from the exposed top surface of the semiconductor substrate 101 (e.g., silicon). Side portions of the sacrificial SiGe layers are covered with the inner spacers 143 during epitaxial growth of first and second source/drain regions 102 and 104. Due to the inner spacers 143 covering the sacrificial SiGe layers, lateral epitaxial growth does not occur from the sacrificial SiGe layers.

According to a non-limiting embodiment of the present invention, the conditions of the epitaxial growth process for the first and second source/drain regions 102 and 104 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr.

After further processing, the first and second source/drain regions 102 and 104 become the source/drain regions for nanosheet transistor structures. For example, in the case of n-type FETs (nFETs), the first and second source/drain regions 102 and 104 (in this example, first source/drain region 102) can comprise in-situ phosphorous doped (ISPD) Si. In the case of p-type FETs (pFETs), the first and second source/drain regions 102 and 104 (in this example, second source/drain region 104) can comprise in-situ boron doped (ISBD) SiGe. The first and second source/drain regions 102 and 104 can be doped at concentrations of about 1×10¹⁹/cm³ to about 3×10²¹/cm³. Other doping methods include, for example, ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). In some embodiments, the stacked structures may both be pFETs or both nFETs or the bottom structures can be pFETs and the top structures can be nFETs.

An inter-layer dielectric (ILD) layer 107 is formed on and around exposed portions of the first and second source/drain regions 102 and 104, and on sides of the gate spacers 145 and the dielectric layer 144. A portion of the ILD layer 107 along with the dielectric layer 144 are formed between and separate the first transistor active area Rx and the second transistor active area Ry. The ILD layer 107 is deposited using deposition techniques such as, for example, CVD, plasma enhanced CVD (PECVD), radio-frequency CVD (RFCVD), physical vapor deposition (PVD), ALD, atomic layer deposition (ALD), molecular beam deposition (MBD), pulsed laser deposition (PLD), and/or liquid source misted chemical deposition (LSMCD), followed by a planarization process, such as, chemical mechanical planarization (CMP). The ILD layer 107 may comprise, for example, SiOₓ, SiOC, SiOCN or some other dielectric.

As noted herein, the sacrificial SiGe layers are selectively removed to create vacant areas where the gate structures 140 are formed in place of the sacrificial SiGe layers. The sacrificial SiGe layers are selectively removed with respect to the channel layers 139, the gate spacers 145 and inner spacers 143. The selective removal can be performed using, for example, a dry HCl etch.

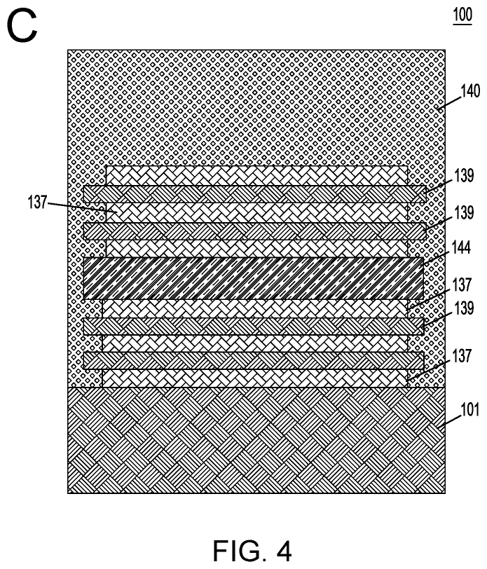

Referring to FIG. 4, in an illustrative embodiment, parts of each sacrificial SiGe layer 137 (e.g., exposed opposite end portions) are selectively removed, while another part of each sacrificial SiGe layer (e.g., central/middle portion) is not removed and remains. In the case of the semiconductor test structure 100 in FIG. 4, the gate structures 140 fill in vacant portions left by the removal of the portions of the sacrificial SiGe layer 137 and are formed adjacent to the remaining portions of the sacrificial SiGe layers 137. Referring to FIG. 4, in the semiconductor test structure 100, portions of the sacrificial SiGe layers 137 remain between the channel layers 139.

Each gate structure 140 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate structures 140 each include a gate region including a work-function metal (WFM) layer, including but not necessarily limited to, for a PFET, titanium nitride (TiN), tantalum nitride (TaN) or ruthenium (Ru), and for an NFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The gate regions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer.

Referring to FIGS. 2A and 3, source/drain contacts 120 are formed in the ILD layer 107 to contact second source/drain regions 104. According to illustrative embodiments, openings corresponding to locations of the source/drain contacts 120 are formed in the ILD layer 107 using, for example, an RIE process. In more detail, portions of the ILD layer 107 exposed via a hardmask (not shown) are etched to form the source/drain contact openings in the ILD layer 107, which are then filled with conductive material (e.g., metal).

The conductive material comprises, for example, a conductor such as, but not necessarily limited to, copper, tungsten, cobalt, ruthenium, etc., and can be deposited in the source/drain contact openings in the ILD layer 107 using, for example, a deposition technique such as CVD, PECVD, RFCVD, PVD, ALD, MBD, PLD, LSMCD, sputtering and/or plating. Deposition may be followed by a planarization process (e.g., CMP) which planarizes the top surface of the semiconductor test structure 100 and removes excess metal material from on top of the ILD layer 107. Prior to depositing the conductive material, according to an embodiment, a barrier layer 105 is formed at a bottom of each of the source/drain contact openings. The barrier layer 105 may comprise, for example, titanium nitride (TiN) or tantalum nitride (TaN). The barrier layer 105 may, for example, comprise a silicide material such as titanium silicide, nickel silicide, nickel platinum silicide, etc. In the case of a silicide, an annealing process can be performed to form the silicide. In some cases, the silicide is formed from the conductive material of the source/drain contacts 120, in which case the conductive material is deposited, and an annealing process can be performed to react the silicon in the underlying second source/drain region 104 with the conductive material to form the silicide. Referring to FIG. 2B, an alternative contact structure comprises a liner layer 122 formed on side and bottom surfaces of a source/drain contact opening. Following deposition of the liner layer 122, a layer of conductive material 121 the same or similar to the conductive material discussed in connection with the source/drain contacts 120 is deposited on the liner layer 122. The liner layer 122 may comprise, for example, TIN, TaN or some other appropriate material.

Referring to FIGS. 2A and 3 respective vias 125 are formed between a plurality of conductive portions 131 forming a metallization layer and the corresponding source/drain contacts 120. The conductive portions 131 are isolated from each other and formed in dielectric layer 130 such as, for example, SiOₓ, SiOC, SiOCN or some other dielectric. As can be seen in FIG. 1, the semiconductor test structure 100 includes multiple dielectric layers 130, multiple vias 125, multiple source/drain contacts 120 and multiple gate structures 140. Vias are also labeled “VA” in FIG. 1.

The conductive portions 131 are formed in the dielectric layer 130 by forming trenches in the dielectric layer 130 and filling the trenches with conductive material. Similarly, the vias 125 are formed in the ILD layer 107 by forming trenches in the ILD layer 107 and filling the trenches with conductive material. Trenches are respectively opened in the dielectric layer 130 and the ILD layer 107 using, for example, lithography followed by RIE. The conductive portions 131, and vias 125 are formed in the trenches by filling the trenches with conductive material, such as, for example, electrically conductive material including, but not necessarily limited to, tungsten, cobalt, zirconium, tantalum, titanium, aluminum, ruthenium, and/or copper. A liner layer (not shown) including, for example, titanium and/or titanium nitride, may be formed on side and bottom surfaces of the trenches before filling the trenches with the conductive material. Deposition of the conductive material can be performed using one or more deposition techniques, including, but not necessarily limited to, CVD, PECVD, PVD, ALD, MBD, PLD, LSMCD, and/or spin-on coating, followed by planarization using a planarization process, such as, for example, CMP.

For the testing process, the conductive portions 131 deliver, for example, current to the source/drain contacts 120 through the vias 125 so that contact resistance between the source/drain contacts 120 and the second source/drain region 104 can be measured. For example, the contact resistance (also referred to herein as interface resistance) is measured at the interface between, for example, the barrier layer 105 and the second source/drain region 104 and/or the liner layer 122 and the second source/drain region 104. The testing may include, for example, Kelvin type tests (e.g., 4-wire Kelvin testing) where high-resolution measurements are taken to determine finite changes in resistance. The second source/drain region 104 is continuous between the plurality of source/drain contacts 120 (e.g., without breaks or isolation). The plurality of source/drain contacts 120 are connected to respective conductive portions 131 through respective vias 125. The respective conductive portions 131 are isolated from each other by the dielectric layer 130, and the respective vias are isolated from each other by the ILD layer 107.

As can be seen by the different sized vertical arrows in FIG. 1 and the different sized horizontal arrows in FIG. 2A, the source/drain contacts 120 are spaced apart from each other at different distances. In addition, as can be seen in FIG. 1, the gate structures 140 extend across an entire dimension (e.g., vertical dimension in FIG. 1) of the first transistor active area (Rx) and the second transistor active area (Ry), which are equal in size (area) to each other and are designated by reference numeral 110.

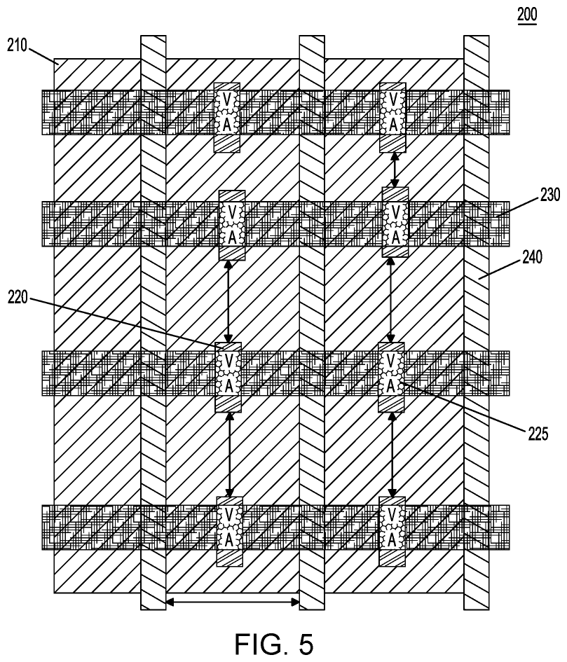

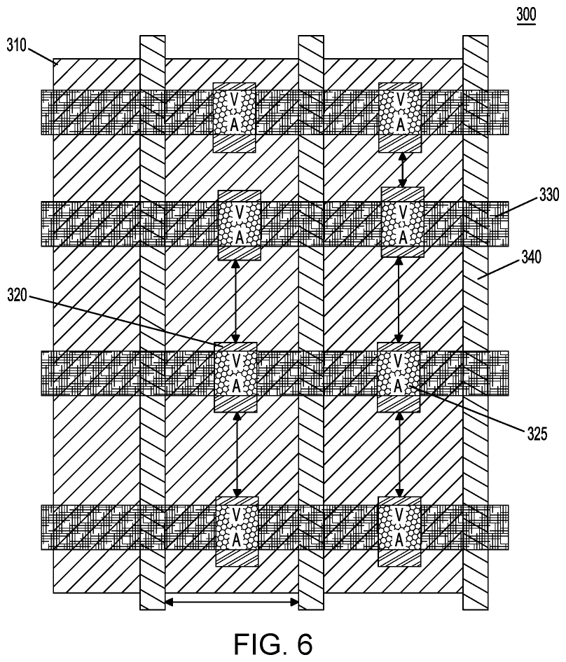

The semiconductor test structures 200 and 300 in FIGS. 5 and 6 are similar to the semiconductor test structure 100 depicted in FIG. 1, and similar reference numerals refer to the same or similar elements (e.g., active areas 210 and 310, source/drain contacts 220 and 320, vias 225 and 325, conductive wires 230 and 330 and gate structures 240 and 340). Like the vias 125 in FIG. 1, vias 225 and 325 in FIGS. 5 and 6 are also labeled “VA.” In the semiconductor test structures 200 and 300 in FIGS. 5 and 6, there are less gate structures than in the semiconductor test structure 100 of FIG. 1 and, as can be seen by the horizontal arrows in FIGS. 1, 5 and 6, the distances between gate structures 140 are different from the distances between gate structures 240 and the distances between gate structures 340. The size of the source/drain contacts can vary. For example, in the semiconductor test structure 300 of FIG. 6, the source/drain contacts 320 are larger than the source/drain contacts 120 and 220 in the semiconductor test structures 100 and 200 of FIGS. 1 and 5.

According to illustrative embodiments, the semiconductor test structures 100, 200 and 300 lack shallow trench isolation (STI) regions. For example, the first and the second transistor active areas Rx and Ry each comprise a plurality of transistors without any STI regions between the plurality of transistors.

Semiconductor structures, devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. An example integrated circuit includes one or more semiconductor devices with the above-described stacked nanosheet test structures.

As noted above, illustrative embodiments correspond to methods for forming structures used for testing contact resistance in stacked FETs, along with illustrative apparatus, systems and devices formed using such methods. At extremely scaled gate pitches, parasitic resistance significantly impacts the performance of devices and contact resistance is extremely important in partition measurement of resistance components. Unlike conventional approaches, the embodiments provide test structures which partition resistance components between gate structures.

It should be understood that the various layers, structures, and regions shown in the figures are schematic illustrations are not drawn to scale. In addition, for case of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor test structure, comprising:
a first transistor active area comprising at least a first source/drain region;
a second transistor active area stacked on the first transistor active area and comprising at least a second source/drain region;
at least one dielectric layer disposed between the first transistor active area and the second transistor active area;
a plurality of contact structures spaced apart from each other and disposed on the second source/drain region; and
at least one gate structure extending across the first transistor active area and the second transistor active area;
wherein contact resistance is measured between respective ones of the plurality of contact structures and the second source/drain region; and
wherein the second source/drain region is continuous between the plurality of contact structures.

2. The semiconductor test structure of claim 1, wherein a size of the first transistor active area is equal to a size of the second transistor active area.

3. The semiconductor test structure of claim 1, wherein the plurality of contact structures are spaced apart from each other at different distances.

4. The semiconductor test structure of claim 1, wherein the first source/drain region has a different doping type than the second source/drain region.

5. The semiconductor test structure of claim 1, wherein:
the first transistor active area comprises a first stacked structure, wherein the first stacked structure comprises a first plurality of gate structures alternately stacked with a first plurality of channel layers; and
the second transistor active area comprises a second stacked structure, wherein the second stacked structure comprises a second plurality of gate structures alternately stacked with a second plurality of channel layers.

6. The semiconductor test structure of claim 5, wherein:
the first transistor active area comprises a first plurality of source/drain regions disposed on sides of the first stacked structure; and
the second transistor active area comprises a second plurality of source/drain regions disposed on sides of the second stacked structure.

7. The semiconductor test structure of claim 5, wherein:
the first transistor active area comprises a first plurality of sacrificial semiconductor layers alternately stacked with the first plurality of channel layers, wherein respective ones of the first plurality of sacrificial semiconductor layers are disposed adjacent to respective ones of the first plurality of gate structures; and
the second transistor active area comprises a second plurality of sacrificial semiconductor layers alternately stacked with the second plurality of channel layers, wherein respective ones of the second plurality of sacrificial semiconductor layers are disposed adjacent to respective ones of the second plurality of gate structures.

8. The semiconductor test structure of claim 1, wherein the semiconductor test structure lacks shallow trench isolation regions.

9. The semiconductor test structure of claim 1, wherein at least the second transistor active area comprises a plurality of transistors without isolation regions between the plurality of transistors.

10. The semiconductor test structure of claim 1, wherein:
the plurality of contact structures are connected to respective ones of a plurality of conductive portions through respective ones of a plurality of vias; and
the respective ones of the plurality of conductive portions are isolated from each other.

11. The semiconductor test structure of claim 1, further comprising a plurality of barrier layers between the plurality of contact structures and the second source/drain region, wherein the contact resistance is measured at respective ones of the plurality of barrier layers.

12. A semiconductor test structure, comprising:
a first active area comprising at least a first nanosheet transistor structure and a first source/drain region corresponding to the first nanosheet transistor structure, wherein the first nanosheet transistor structure comprises a first plurality of gate structures alternately stacked with a first plurality of channel layers;
a second active area stacked on the first active area and comprising at least a second nanosheet transistor structure and a second source/drain region corresponding to the second nanosheet transistor structure, wherein the second nanosheet transistor structure comprises a second plurality of gate structures alternately stacked with a second plurality of channel layers;
at least one dielectric layer disposed between the first active area and the second active area; and
a plurality of contact structures spaced apart from each other and disposed on the second source/drain region;
wherein contact resistance is measured between respective ones of the plurality of contact structures and the second source/drain region; and
wherein the second source/drain region is continuous between the plurality of contact structures.

13. The semiconductor test structure of claim 12, wherein a size of the first active area is equal to a size of the second active area.

14. The semiconductor test structure of claim 12, wherein the plurality of contact structures are spaced apart from each other at different distances.

15. The semiconductor test structure of claim 12, wherein:
the first active area comprises a first plurality of sacrificial semiconductor layers alternately stacked with the first plurality of channel layers, wherein respective ones of the first plurality of sacrificial semiconductor layers are disposed adjacent to respective ones of the first plurality of gate structures; and
the second active area comprises a second plurality of sacrificial semiconductor layers alternately stacked with the second plurality of channel layers, wherein respective ones of the second plurality of sacrificial semiconductor layers are disposed adjacent to respective ones of the second plurality of gate structures.

16. The semiconductor test structure of claim 12, wherein at least the second active area lacks shallow trench isolation regions.

17. A semiconductor test structure, comprising:
a substrate;
a first active area comprising a first source/drain region disposed on the substrate, the first source/drain region having a first doping type;
a dielectric layer disposed on the first source/drain region;
a second active area comprising a second source/drain region disposed on the dielectric layer, the second source/drain region having a second doping type different from the first doping type;
a plurality of contact structures spaced apart from each other and disposed on the second source/drain region; and
at least one gate structure extending across at least the second active area;
wherein contact resistance is measured between respective ones of the plurality of contact structures and the second source/drain region; and
wherein the second source/drain region is continuous between the plurality of contact structures.

18. The semiconductor test structure of claim 17, wherein an area of the first active area is equal to an area of the second active area.

19. The semiconductor test structure of claim 17, wherein the plurality of contact structures are spaced apart from each other at different distances.

20. The semiconductor test structure of claim 17, further comprising a plurality of barrier layers between the plurality of contact structures and the second source/drain region, wherein the contact resistance is measured at respective ones of the plurality of barrier layers.
